(19) United States
(12) Patent Application Publication
(10) Pub. No.: US 2006/0255328 A1
(43) Pub. Date: Nov. 16, 2006

(54) Using conductive oxidation for phase change memory electrodes

(76) Inventor: Charles H. Dennison, San Jose, CA (US)

Correspondence Address: TROP PRUNER & HU, PC, 1616 S. VOSS ROAD, SUITE 750, HOUSTON, TX, 77057-2631, US

(21) Appl. No.: 11/127,556

(22) Filed: May 12, 2005

(51) Int. Cl. H01L 47/00

(52) U.S. Cl. 257/4

(57) ABSTRACT

A memory may include a phase change memory material having an electrode including a material that is a conductive oxide or that forms a conductive oxide.

### BACKGROUND

This invention relates generally to phase change memory devices.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

During the fabrication of phase change memories, electrodes within a memory cell may oxidize, leading to significant resistance increases. These increases may result in defective products. The number of cells in memories failing the high resistance tests may be reduced by taking great care in the processing steps and step sequences to minimize any opportunity for oxidation. However, such steps add to the cost of manufacturing the products and may not always be completely effective.

Thus, there is a need for better ways to reduce the resistance increase, product failures, or other adverse consequences of electrode oxidation in phase change memories.

### BRIEF DESCRIPTION OF THE DRAWINGS

FIG. 1 is a schematic diagram illustrating a memory in accordance with one embodiment of the present invention;

FIG. 2 is a diagram illustrating a current-voltage characteristic of a select device;

FIG. 3 is a diagram illustrating a current-voltage characteristic of another select device;

FIG. 4 is a cross-sectional view of a portion of the memory illustrated in FIG. 1 in accordance with an embodiment of the present invention; and

FIG. 5 is a block diagram illustrating a portion of a system in accordance with an embodiment of the present invention.

### DETAILED DESCRIPTION

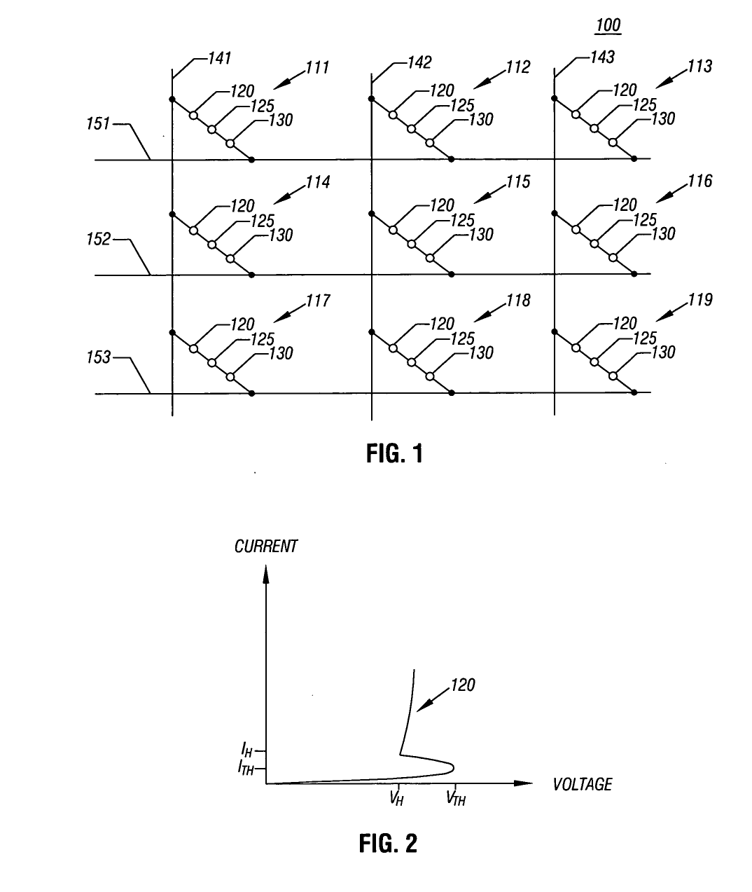

Turning to FIG. 1, an embodiment of a memory 100 is illustrated. Memory 100 may include a 3×3 array of memory cells 111-119, wherein memory cells 111-119 each include a select device 120, a select device 125, and a memory element 130. Although a 3×3 array is illustrated in FIG. 1, the scope of the present invention is not limited in this respect. Memory 100 may have a larger array of memory cells.

In one embodiment, memory elements 130 may comprise a phase change material. In this embodiment, memory 100 may be referred to as a phase change memory. A phase change material may be a material having electrical properties (e.g. resistance, capacitance, etc.) that may be changed through the application of energy such as, for example, heat, light, voltage potential, or electrical current. The phase change material may include a chalcogenide material.

A chalcogenide alloy may be used in a memory element or in an electronic switch. A chalcogenide material may be a material that includes at least one element from column VI of the periodic table or may be a material that includes one or more of the chalcogen elements, e.g., any of the elements of tellurium, sulfur, or selenium.

Memory 100 may include column lines 141-143 and row lines 151-153 to select a particular memory cell of the array during a write or read operation. Column lines 141-143 and row lines 151-153 may also be referred to as address lines since these lines may be used to address memory cells 111-119 during programming or reading. Column lines 141-143 may also be referred to as bit lines and row lines 151-153 may also be referred to as word lines.

Memory elements 130 may be connected to row lines 151-153 and may be coupled to column lines 141-143 via select devices 120, 125. Therefore, when a particular memory cell (e.g., memory cell 115) is selected, voltage potentials may be applied to the memory cell's associated column line (e.g., 142) and row line (e.g., 152) to apply a voltage potential across the memory cell.

Series connected select devices 120 and 125 may be used to access memory element 130 during programming or reading of memory element 130. A select device may be an ovonic threshold switch that can be made of a chalcogenide alloy that does not exhibit an amorphous to crystalline phase change and which undergoes rapid, electric field initiated change in electrical conductivity that persists only so long as a holding voltage is present.

Select devices 120, 125 may operate as a switch that is either “off” or “on” depending on the amount of voltage potential applied across the memory cell, and more particularly whether the current through the select device exceeds its threshold current or voltage, which then triggers the device into the on state. The off state may be a substantially electrically nonconductive state and the on state may be a substantially conductive state, with less resistance than the off state.

In the on state, the voltage across the select device is equal to its holding voltage V_{H} plus IxRon, where Ron is the dynamic resistance from the extrapolated X-axis intercept, V_{H}. For example, select devices 120, 125 may have threshold voltages and, if a voltage potential less than the threshold voltage of a select device 120, 125 is applied across select devices 120, 125, then at least one select device 120 or 125 may remain “off” or in a relatively high resistive state so that little or no electrical current passes through the memory cell and most of the voltage drop from selected row to selected column is across the select device. Alternatively, if a voltage potential greater than the threshold voltages of select devices 120, 125 is applied across select devices 120, 125, then both select devices 120, 125 may “turn on,” i.e., operate in a relatively low resistive state so that electrical current passes through the memory cell. In other words, select devices 120, 125 may be in a substantially electrically nonconductive state if less than a predetermined voltage potential, e.g., the threshold voltage, is applied across select devices 120, 125. Select devices 120, 125 may be in a substantially conductive state if greater than the predetermined voltage potential is applied across select devices 120, 125. Select devices 120, 125 may also be referred to as an access device, an isolation device, or a switch.

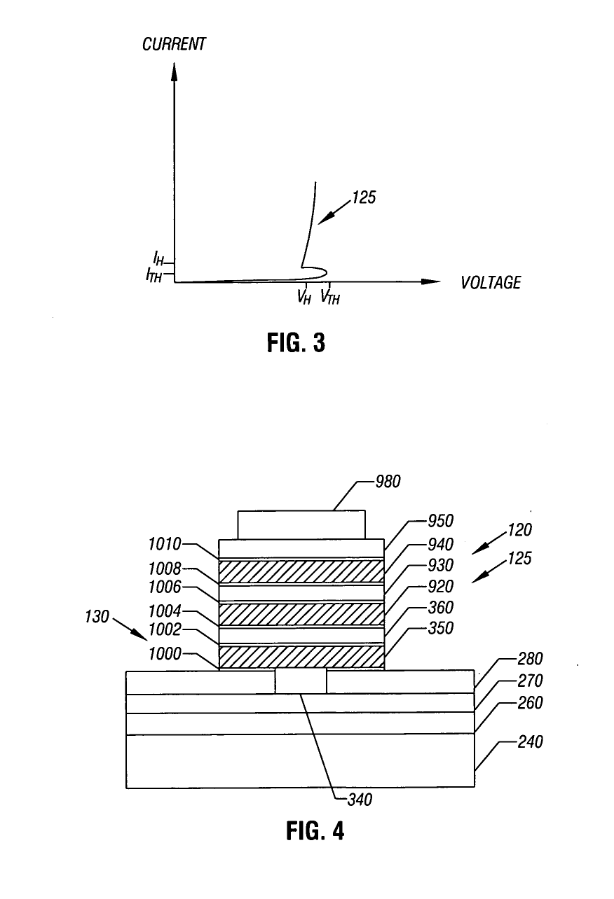

In one embodiment, each select device 120, 125 may comprise a switching material such as, for example, a chalcogenide alloy, and may be referred to as an ovonic threshold switch, or simply an ovonic switch. The switching material of select devices 120, 125 may be a material in a substantially amorphous state positioned between two electrodes that may be repeatedly and reversibly switched between a higher resistance “off” state (e.g., greater than about ten megaohms) and a relatively lower resistance “on” state (e.g., about one thousand Ohms in series with V_{H}) by application of a predetermined electrical current or voltage potential. In this embodiment, each select device 120, 125 may be a two terminal device that may have a current-voltage (I-V) characteristic similar to a phase change memory element that is in the amorphous state. However, unlike a phase change memory element, the switching material of select devices 120, 125 may not change phase. That is, the switching material of select devices 120, 125 may not be a programmable material, and, as a result, select devices 120, 125 may not be a memory device capable of storing information. For example, the switching material of select devices 120, 125 may remain permanently amorphous and the I-V characteristic may remain the same throughout the operating life. A representative example of I-V characteristics of select devices 120, 125 is shown in FIGS. 2 and 3.

Turning to FIG. 2, in the low voltage or low electric field mode, i.e., where the voltage applied across select device 120 is less than a threshold voltage (labeled V_{TH}), select device 120 may be “off” or nonconducting, and exhibit a relatively high resistance, e.g., greater than about 10 megaohms. Select device 120 may remain in the off state until a sufficient voltage, e.g., V_{TH}, is applied, or a sufficient current is applied, e.g., I_{TH}, that may switch select device 120 to a conductive, relatively low resistance on state. After a voltage potential of greater than about V_{TH} is applied across select device 120, the voltage potential across select device 120 may drop (“snapback”) to a holding voltage potential, labeled V_{H}. Snapback may refer to the voltage difference between V_{TH} and V_{H} of a select device.

In the on state, the voltage potential across select device 120 may remain close to the holding voltage of V_{H} as current passing through select device 120 is increased. Select device 120 may remain on until the current through select device 120 drops below a holding current, labeled I_{H}. Below this value, select device 120 may turn off and return to a relatively high resistance, nonconductive off state until the V_{TH} and I_{TH} are exceeded again.

In one embodiment, the device 120 (FIG. 2) may have a higher resistance and a higher threshold voltage (V_{TH}) than the device 125 (FIG. 3). The device 120 may also have a higher activation energy. The threshold and holding voltages of the device 125 may be substantially equal and, in one embodiment, the snapback voltage is less than 0.25 volts. The device 125 may have higher leakage than the device 120 and may have a V_{TH} substantially equal to or less than its V_{H}. If the V_{TH} is less than V_{H}, snapback voltage is minimized. Preferably, V_{H} of device 125 is greater than snapback voltage of device 120. When both devices 120 and 125 are switched on, the V_{H} of the two devices in series is equal to the sum of the hold voltage across each device when both devices are on.

In some embodiments, only one select device may be used. In other embodiments, more than two select devices may be used. A single select device may have a V_{H} about equal to its threshold voltage, V_{TH}, (a voltage difference less than the threshold voltage of the memory element) to avoid triggering a reset bit when the select device triggers from a threshold voltage to a lower holding voltage called the snapback voltage. An another example, the threshold current of the memory element may be about equal to the threshold current of the access device even though its snapback voltage is greater than the memory element's reset bit threshold voltage.

One or more MOS or bipolar transistors or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

Turning to FIG. 4, an embodiment of a memory cell (e.g., 115) of memory 100 is arranged in a vertical stack in one embodiment of the present invention. However, other configurations may also be used including configurations in which the order of the devices is changed, and including configurations with two or three discrete stacks wired in series. Memory cell 115 may comprise substrate 240, insulating material 260 overlying substrate 240, and conductive material 270 overlying insulating material 260. Conductive material 270 may be an address line (e.g., row line 152). Above conductive material 270, electrode 340 may be formed between portions of insulating material 280.

Over electrode 340, sequential layers of a memory material 350, electrode material 360, a switching material 920, such as a non-programmable chalcogenide with a lower threshold current and higher threshold voltage relative to its V_{H}, an electrode material 930, a switching material 940, such as a non-programmable chalcogenide with a higher threshold current and lower threshold voltage about equal to V_{H}, an electrode material 950, and a conductive material 980 may be deposited to form a vertical memory cell structure. Conductive material 980 may be an address line (e.g., column line 142).

The substrate 240 may be, for example, a semiconductor substrate (e.g., a silicon substrate), although the scope of the present invention is not limited in this respect. Other suitable substrates may be, but are not limited to, substrates that contain ceramic material, organic material, or a glass material.

A layer of insulating material 260 may be formed over and contacting substrate 240. Insulating material 260 may be a dielectric material that may be a thermally and/or electrically insulating material such as, for example, silicon dioxide, although the scope of the present invention is not limited in this respect. Insulating material 260 may have a thickness ranging from about 300 Å to about 10,000 Å, although the scope of the present invention is not limited in this respect. Insulating material 260 may be planarized using a chemical or chemical-mechanical polish (CMP) technique.

A thin film of a conductive material 270 may be formed overlying insulating material 270 using, for example, a physical vapor deposition (PVD) process. Conductive material 270 may be patterned using photolithographic and etch techniques to form a small width in the y-direction (orthogonal to the view shown in FIG. 4). The film thickness of conductive material 270 may range from about 20 Å to about 2000 Å. In one embodiment, the thickness of conductive material 270 may range from about 200 Å to about 1000 Å. In another embodiment, the thickness of conductive material 270 may be about 500 Å.

Conductive material 270 may be an address line of memory 100 (e.g., row line 151, 152, or 153). Conductive material 270 may be, for example, a tungsten (W) film, a doped polycrystalline silicon film, a Ti film, a TiN film, a TiW film, an aluminum (Al) film, a copper (Cu) film, or some combination of these films. In one embodiment, conductive material 270 may be a polycrystalline silicon film with a resistance lowering strap of a refractory silicide on its top surface, although the scope of the present invention is not limited in this respect.

An insulating dielectric material 280 may be formed overlying conductive material 270 using, for example, a PECVD (Plasma Enhanced Chemical Vapor Deposition) process, HDP (High Density Plasma) process, or spin-on and bake sol gel process. Insulating material 280 may be a dielectric material that may be a thermally and/or electrically insulating material such as, for example, silicon dioxide, although the scope of the present invention is not limited in this respect. Insulating material 280 may have a thickness ranging from about 100 Å to about 4000 Å, although the scope of the present invention is not limited in this respect. In one embodiment, the thickness of insulating material 280 may range from about 500 Å to about 2500 Å. In another embodiment, the thickness of insulating material 280 may be about 1200 Å.

Although the scope of the present invention is limited in this respect, insulating material 280 may be planarized using a chemical or CMP technique. The resulting thickness of insulating material 280 may range from about 20 Å to about 4000 Å. In one embodiment, after planarizing insulating material 280, the thickness of insulating material 280 may range from about 200 Å to about 2000 Å. In another embodiment, the thickness of insulating material 280 may be about 900 Å.

Memory material 350 may be a phase change, programmable material capable of being programmed into one of at least two memory states by applying a current to memory material 350 to alter the phase of memory material 350 between a substantially crystalline state and a substantially amorphous state, wherein a resistance of memory material 350 in the substantially amorphous state is greater than the resistance of memory material 350 in the substantially crystalline state.

Programming of memory material 350 to alter the state or phase of the material may be accomplished by applying voltage potentials to conductive materials 340 and 980, thereby generating a voltage potential across select devices 120, 125 and memory element 130. When the voltage potential is greater than the threshold voltages of select devices 120, 125 and memory element 130, then an electrical current may flow through memory material 350 in response to the applied voltage potentials, and may result in heating of memory material 350.

This heating may alter the memory state or phase of memory material 350. Altering the phase or state of memory material 350 may alter the electrical characteristic of memory material 350, e.g., the resistance of the material may be altered by altering the phase of the memory material 350. Memory material 350 may also be referred to as a programmable resistive material.

In the “reset” state, memory material 350 may be in an amorphous or semi-amorphous state and in the “set” state, memory material 350 may be in an a crystalline or semi-crystalline state. The resistance of memory material 350 in the amorphous or semi-amorphous state may be greater than the resistance of memory material 350 in the crystalline or semi-crystalline state. It is to be appreciated that the association of reset and set with amorphous and crystalline states, respectively, is a convention and that at least an opposite convention may be adopted.

Using electrical current, memory material 350 may be heated to a relatively higher temperature to amorphosize memory material 350 and “reset” memory material 350 (e.g., program memory material 350 to a logic “0” value). Heating the volume of memory material 350 to a relatively lower crystallization temperature may crystallize memory material 350 and “set” memory material 350 (e.g., program memory material 350 to a logic “1” value). Various resistances of memory material 350 may be achieved to store information by varying the amount of current flow and duration through the volume of memory material 350.

Glue layers 1000 and 1002 may be formed on opposite sides of the material 350. The layers 1000 and 1002 may have a thickness of less than 500 Angstroms. The layers 1000 and 1002 may improve the adherence of the material 350 to over and underlying layers. The layers 1000 and 1002 may be an alloy of the form TiaXNb where X may, for example, be silicon, aluminum, carbon, or boron, as a few examples. If the layer 1000 is conductive, an insulating spacer (not shown) may be located between the electrode 340 and the layer 1000. The nitrogen, which may be in the form of nitride, may be anywhere from 0 to about 50 atomic percent in some embodiments. In one advantageous embodiment, the nitrogen content may be about 30 atomic percent. The layer may be applied by reactive sputtering with controlled N₂ flow.

According to another embodiment, the layers 1000 and 1002 may be formed of TiSix where x is from 1 to 2, including TiSi and TiSi₂. In this case, the Si material may reduce titanium diffusion.

Glue layers 1004, 1006, 1008, and 1010 may be used in some embodiments as well. They may be designed in the same way as the glue layers 1000, 1002 described above.

Select device 125 may include a bottom electrode 360 and a switching material 920 overlying bottom electrode 360 as shown in FIG. 4. In other words, switching material 920 may be formed over and contacting bottom electrode 360. In addition, select device 125 may include a top electrode 930 overlying switching material 920.

Although the scope of the present invention is not limited in this respect, bottom electrode 360 may be a thin film material having a film thickness ranging from about 20 Angstroms (Å) to about 2000 Å. In one embodiment, the thickness of electrode 360 may range from about 100 Å to about 1000 Å. In another embodiment, the thickness of electrode 360 may be about 300 Å. Suitable materials for bottom electrode 360 may include any material that is a conductive oxide or any material that forms a conductive oxide including ruthenium, iridium, and alloys of materials that form conductive oxides including strontium ruthenium alloy. For example, RuO₂ has a bulk resistivity of 35 mV-cm.

The electrodes 340, 930, and 950 may also be made of a material that is a conductive oxide or that forms a conductive oxide. In some embodiments, suitable materials or their oxides may exhibit bulk resistivity of less than about 50 mV-cm.

Although the scope of the present invention is not limited in this respect, switching material 920 may be a thin film material having a thickness ranging from about 20 Å to about 2000 Å. In one embodiment, the thickness of switching material 920 may range from about 200 Å to about 1000 Å. In another embodiment, the thickness of switching material 920 may be about 500 Å.

Switching material 920 may be formed overlying bottom electrode 360 using a thin film deposition technique such as, for example, a chemical vapor deposition (CVD) process or a physical vapor deposition (PVD). Switching material 920 may be a thin film of a chalcogenide material or an ovonic material in a substantially amorphous state that may be repeatedly and reversibly switched between a higher resistance “off” state and a relatively lower resistance “on” state by application of a predetermined electrical current or voltage potential. Switching material 920 may be a nonprogammable material.

Although the scope of the present invention is not limited in this respect, in one example, the composition of switching material 920 may comprise a Si concentration of about 14%, a Te concentration of about 39%, an As concentration of about 37%, a Ge concentration of about 9%, and an In concentration of about 1%. In another example, the composition of switching material 940 may comprise a Si concentration of about 14%, a Te concentration of about 39%, an As concentration of about 37%, a Ge concentration of about 9%, and a P concentration of about 1%. In these examples, the percentages are atomic percentages which total 100% of the atoms of the constituent elements.

In another embodiment, a composition for switching material 920 may include an alloy of arsenic (As), tellurium (Te), sulfur (S), germanium (Ge), selenium (Se), and antimony (Sb) with respective atomic percentages of 10%, 21%, 2%, 15%, 50%, and 2%.

Although the scope of the present invention is not limited in this respect, in other embodiments, switching material 920 may include Si, Te, As, Ge, sulfur (S), and selenium (Se). As an example, the composition of switching material 940 may comprise a Si concentration of about 5%, a Te concentration of about 34%, an As concentration of about 28%, a Ge concentration of about 11%, a S concentration of about 21%, and a Se concentration of about 1%.

Top electrode 930 may be a thin film material having a thickness ranging from about 20 Å to about 2000 Å. In one embodiment, the thickness of electrode 930 may range from about 100 Å to about 1000 Å. In another embodiment, the thickness of electrode 930 may be about 300 Å. Suitable materials for top electrode 930 may include a thin film of a material that forms a conductive oxide and alloys and combinations of such materials.

In one embodiment, the top electrode 930 and bottom electrode 360 may comprise ruthenium and may have a thickness of about 500 Å. Top electrode 930 may also be referred to as an upper electrode and bottom electrode 360 may also be referred to as a lower electrode. In this embodiment, select device 125 may be referred to as a vertical structure since electrical current may flow vertically through switching material 920 between top electrode 930 and bottom electrode 360. Select device 125 may be referred to as a thin film select device if thin films are used for switching material 920 and electrodes 930 and 360.

The threshold current (I_{TH}) of select device 125 may be less than the threshold current for an ovonic memory device set in a high resistance, amorphous state. The resistance of the select devices 120, 125 at the time that the select devices switch on may be much greater, such as ten times greater, than the resistance of the memory element 130, so that when a select device 120 or 125 is switched on, most of the voltage is across the select device to minimize variation in the voltage at which the select device switches. The threshold voltage (V_{TH}) of select device 125 may be altered by changing process variables such as, for example, the thickness or alloy composition of switching material 920 and the active area of the contacting electrode. For example, increasing the thickness of switching material 920 may increase the threshold voltage of select device 125, with the result that the snapback voltage is increased if V_{H} of the device remains the same. The holding voltage (V_{H}) of select device 125 may be altered or set by the type of contact to switching device 125, e.g., the composition of electrodes 360 and 930 may determine the holding voltage of select device 125.

Switching material 940 and electrodes 930 and 950 may form select device 120. Switching material 940 may be formed using similar but different materials and similar but different manufacturing techniques used to form switching material 920 described herein. Switching materials 920 and 940 may be composed of different materials. For example, in one embodiment, switching material 920 may be composed of a chalcogenide material and switching material 940 may be composed of a different chalcogenide material.

In one embodiment, the switching material 920 may be thinner than the thickness of switching material 940 to reduce leakage. Alternatively, the material 920 may be made of a lower leakage alloy such as an allow with a higher semiconductor bandgap in the range of 0.8 eV to 1.0 eV, such as an As, Se, Ge alloy with 20% to 40% Ge. One suitable alloy includes (in atomic percentages) 10% As, 21% Te, 2% S, 15% Ge, 50% Se and 2% Sb, with a bandgap of about 0.85 eV. As another example, the switching element 920 may have a smaller area measured in the horizontal direction to reduce leakage.

The device 125 may be made using a different alloy as the switching material 940 (e.g., Te 39%, As 37%, Si 17%, Ge 7%), with 10 to 20% added silicon in one embodiment. The alloy for the material 940 may be a higher leakage alloy.

In this embodiment, the threshold voltage of select device 120 may be about 3 volts and the holding voltage of select device 120 may be about one volt. The threshold voltage of select device 125 may be about 1.1 or less volts and the holding voltage of select device 125 may be about one volt. The threshold voltage of the device 130 may be less than the snapback voltage of the series combination of devices 120 and 125, so that V_{TH} of the memory device 130 is not exceeded when the select device snaps back. To further reduce the snapback voltage, more than one device like the device of 125 may be placed in series with the device of 120. As still another option, the device 120 may be made of a material with a higher activation energy. In some embodiments, the device 120 may be formed of a chalcogenide having a higher glass transition temperature.

Further, the leakage and the threshold current of the device 120 may be less than the leakage of the device 125 and the memory element 130 so that, until the device 120 triggers (as its voltage exceeds its threshold voltage), the voltage across the device 125 and the element 130 may be minimized to a relatively insignificant voltage, and the leakage into the series combination minimized when deselected. In one embodiment, that voltage across device 130 may be less than 10% of the voltage across the device 120 until it is triggered. For example, the resistance across the device 125 and the element 130 can be ten times less than the resistance across the device 120 until the device 120 triggers by exceeding its threshold voltage. The increase in threshold voltage for the combined series set of the devices is a resistor divider across the device 120. That is, the increase, relative to the total voltage across selected row and column voltage, that is across device 120 is proportionate to the voltage dropped across the device 125 and the element 130, which can be reduced by increasing the leakage and decreasing the resistance of the device 125 relative to device 120 at the time device 120 switches on. Maintaining the series devices 120 and 125 in the V_{H} on state is assured by maintaining the current greater than I_{H} of both after they switch on, and the holding current and threshold currents (I_{TH}) of the select device 120 or 125 (I_{TH}) may be adjusted to be less than the I_{TH} current of memory element 130.

For example, if the device 120 triggers at 3.3 volts across the select devices 120 and 125 and memory element 130 to a holding voltage of one volt, this leaves 2.3 volts across the remaining device 125 and a memory element 130. The 2.3 volts is adequate to trigger device 125, and the relative resistances of device 125 and 130 may be such that most of the voltage is across the device 125 so only it switches, leaving the memory element 130 unswitched with the balance of the voltage across it (above voltage device 120 +V_{H} device 125) so that the holding voltage of the device 125 is added to the holding voltage of the device 120, with the balance of the voltage across the memory element 130. The resulting snapback voltage of the combination of devices 120 and 130 is 3.3 V minus V_{H} Of device 120 minus V_{H} of device 125 minus the voltage across element 130, say 1.3V. This voltage can be further reduced by increasing the holding voltage of any of the devices or by reducing the threshold voltage of any of the devices 120 or 125 or by adding addition devices 125 to the series combination.

After the devices 120 and 125 trigger, the balance of the voltage developed on the bitline, above the row line, is then across the memory element 130. As the voltage increases when the column line is driven by a current source, the voltage can be read as a one when the element 130 is reset because the column line voltage keeps increasing and exceeds the sensor or reference voltage. If, after a reasonable period of time, the column line does not exceed the reference voltage, then the bit is set and in the lower resistance state.

For a combined select device and memory element that has no snapback, the total voltage across the combined devices 120 and 125 increases as the increasing current is forced into the pair. If the threshold voltage of the device 120 is equal to the holding voltage of the device 120 plus the holding voltage of the device 125, and the threshold voltage of the device 125 equals the holding voltage of the device 125, then the snapback voltage of the device 120 is absorbed in the increase of voltage across the device 125 without the device 130 thresholding, then the selection devices in series appear to have no snapback voltage in combination. To absorb the snapback voltage of the first device, the threshold voltage of the device 120, minus the holding voltage of the device 120, must be less than the threshold voltage of 125, which is preferably less than holding voltage of the device 125.

As an example, if the threshold voltage of the device 125 equals the holding voltage of the device 125, which in this example is 1.5 volts, and the threshold voltage of the device 120 is 2.6 volts with a holding voltage of 1.5 volts, then the voltage across the device 125 at the threshold of the device 120 is equal to 0.4. The resistance of the device 125 at a threshold current of the device 120 flowing through it may be about 10% of the resistance of the device 120 at its threshold voltage. So immediately prior to the device 120 thresholding, the voltage across the device 120 is 2.6 volts, the voltage across the device 125 is 0.3 volts and the total voltage is 2.9 volts.

After the device 120 thresholds, the voltage across the device 120 is equal to the holding voltage of the device 120 or 1.5 volts, while the voltage across the device 125 is 1.4 volts, which is still below both the threshold voltage and the holding voltage of the memory element. The total voltage then is 2.9 volts without snapbacks since an additional 0.1 volt needs to be applied across the device 125 before it snaps back.

Because one or more of the electrodes in the phase change memory cell is formed with a material that when oxidized forms a conductive oxide, resistivity changes may be less pronounced in some embodiments. This may result in better yield and better performance in some cases.

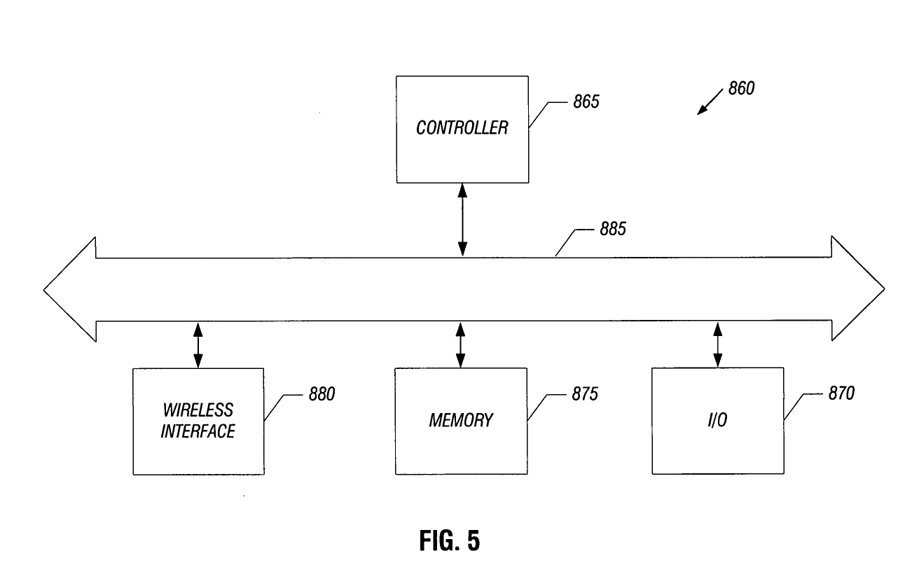

Turning to FIG. 5, a portion of a system 860 in accordance with an embodiment of the present invention is described. System 860 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 860 may be used in any of the following systems: a wireless local area network (WLAN) system, a wireless personal area network (WPAN) system, a cellular network, although the scope of the present invention is not limited in this respect.

System 860 may include a controller 865, an input/output (I/O) device 870 (e.g. a keypad, display), a memory 875, and a wireless interface 880 coupled to each other via a bus 885. It should be noted that the scope of the present invention is not limited to embodiments having any or all of these components.

Controller 865 may comprise, for example, one or more microprocessors, digital signal processors, microcontrollers, or the like. Memory 875 may be used to store messages transmitted to or by system 860. Memory 875 may also optionally be used to store instructions that are executed by controller 865 during the operation of system 860, and may be used to store user data. Memory 875 may be provided by one or more different types of memory. For example, memory 875 may comprise any type of random access memory, a volatile memory, a non-volatile memory such as a flash memory and/or a memory such as memory 100 discussed herein.

I/O device 870 may be used by a user to generate a message. System 860 may use wireless interface 880 to transmit and receive messages to and from a wireless communication network with a radio frequency (RF) signal. Examples of wireless interface 880 may include an antenna or a wireless transceiver, although the scope of the present invention is not limited in this respect.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

What is claimed is:

1. An apparatus, comprising:
a first and second electrodes, said first electrode including a material that forms a conductive oxide; and
a phase change memory material between said electrodes.

2. The apparatus of claim 1 wherein said first electrode includes ruthenium.

3. The apparatus of claim 1 wherein said first electrode includes iridium.

4. The apparatus of claim 1 wherein said first electrode includes an alloy of ruthenium.

5. The apparatus of claim 1 wherein said first electrode is formed of a material that forms an oxide having a bulk resistivity less than 50 mV-cm.

6. The apparatus of claim 1 wherein both of said electrodes are formed of a material that forms a conductive oxide.

7. The apparatus of claim 1 wherein said first electrode includes a conductive oxide.

8. The apparatus of claim 1 wherein said first electrode includes a metal that forms a conductive oxide.

9. The apparatus of claim 1 wherein said phase change memory material a chalcogenide.

10. A method comprising:
forming an electrode in a phase change memory using a material that forms a conductive oxide.

11. The method of claim 10 including forming said electrode to include ruthenium.

12. The method of claim 10 including forming said electrode to include iridium.

13. The method of claim 10 including forming an electrode to include an alloy of ruthenium.

14. The method of claim 10 including forming said electrode of a material that forms an oxide having a bulk resistivity less than 50 mV-cm.

15. The method of claim 10 including forming said memory with two electrode to form a conductive oxide.

16. The method of claim 10 including forming said electrode of a conductive oxide.

17. The method of claim 10 including forming said electrode of a metal that forms a conductive oxide.

18. A system, comprising:
a processor;
a wireless interface coupled to the processor; and
a memory coupled to the processor, the memory including:
a first and second electrodes, said first electrode including a material that forms a conductive oxide; and
a phase change memory material between said electrodes.

19. The system of claim 18 wherein said first electrode includes ruthenium.

20. The system of claim 18 wherein said first electrode includes iridium.

21. The system of claim 18 wherein said first electrode includes an alloy of ruthenium.

22. The system of claim 18 wherein said first electrode is formed of a material that forms an oxide having a bulk resistivity of less than 50 mV-cm.

23. The system of claim 19 wherein said phase change memory material includes a chalcogenide.

24. The system of claim 19 wherein said interface includes a dipole antenna.

25. The system of claim 19 wherein said electrodes form conductive oxides.
